(19) United States
(12) Patent Application Publication
(10) Pub. No.: US 2013/0189622 A1
(43) Pub. Date: Jul. 25, 2013

(54) BLOCK COPOLYMER OF POLYMIDE AND POLYAMIC ACID, METHOD FOR PRODUCING THE BLOCK COPOLYMER, PHOTOSENSITIVE RESIN COMPOSITION COMPRISING THE BLOCK COPOLYMER AND PROTECTIVE FILM FORMED USING THE BLOCK COPOLYMER

(71) Applicant: LG CHEM, LTD., Seoul (KR)

(72) Inventors: Sang-Woo KIM, Daejeon (KR); Dong-Hyun OH, Oaejeon (KR); Hye-In SHIN, Seoul (KR); Hye-Ran SEONG, Daejeon (KR); Chan-Hyo PARK, Daejeon (KR); Kyung-Jun KIM, Daejeon (KR)

(73) Assignee: LG CHEM, LTD., Seoul (KR)

(21) Appl. No.: 13/796,526

(22) Filed: Mar. 12, 2013

Related U.S. Application Data
(62) Division of application No. 12/458,352, filed on Jul. 8, 2009, now abandoned.

(30) Foreign Application Priority Data
Jul. 9, 2008 (KR) 10-2008-0066567

(51) Int. Cl. G03F 7/039

(52) U.S. Cl. CPC G03F 7/0395
USPC 430/270.1; 528/322

(57) ABSTRACT

A block copolymer of a polyimide and a polyamic acid is disclosed. Further disclosed are a method for producing the block copolymer and a positive type photosensitive composition comprising the block copolymer. The solubility of the photosensitive composition in an alkaline aqueous solution is controlled to achieve high resolution of a pattern. Further disclosed are a protective film of a semiconductor device and an ITO insulating film of an organic light emitting diode (OLED), which are formed using the block copolymer. The protective film and the ITO insulating film are very stable over time.

### BACKGROUND OF THE INVENTION

1. Field of the Invention

The present invention relates to a block copolymer of a polyimide and a polyamic acid (hereinafter, referred to simply as a ‘polyimide-polyamic acid copolymer’), a method for producing the polyimide-polyamic acid copolymer, a photosensitive composition comprising the polyimide-polyamic acid copolymer, and a protective film composed of a polyimide film formed using the polyimide-polyamic acid copolymer.

2. Description of the Related Art

Generally, an insulating film of an organic light emitting diode (OLED) or a protective film of a semiconductor device is produced by applying a photoresist to a polyimide film, patterning the polyimide film, and etching the patterned film with an organic solvent. However, this method is complicated and has the problem that the organic solvent swells the resist pattern.

The use of a negative type photosensitive polyimide eliminates the need for an additional photoresist, contributing to the simplification of processing. However, the problem still remains unsolved that an organic solvent swells a resist pattern, leading to deterioration in the resolution of the final film pattern.

In order to solve the above problem, many attempts have recently been made. For example, a negative type photosensitive polyimide film formed using an alkaline aqueous solution as an etching solution has been successfully developed and is currently produced on an industrial scale. However, since uncrosslinked carboxyl groups and alcoholic hydroxyl groups remain in the negative type photosensitive polyimide in an unexposed region during development, slight swelling occurs by the alkaline aqueous solution, and as a result, the final resist pattern has shoulder portions whose shape is round in cross section, thus failing to obtain high quality.

Under these circumstances, considerable research efforts have been made in developing positive type photosensitive polyimide films that use photosensitive resins, which reduces the number of processing steps, are developed with alkaline aqueous solutions instead of organic solvents, which is environmentally friendly, and achieve higher resolution than negative type photosensitive polyimide films.

Most positive type photosensitive resin compositions developed hitherto are a combination of a polyamic acid and a diazonaphthoquinone, a combination of a polyamic acid-polyimide copolymer and a diazonaphthoquinone, a combination of a polyimide and a diazonaphthoquinone, a combination of a polybenzoxazole and a diazonaphthoquinone, and a combination of a chemically amplified polyamic acid ester and a photoacid generator.

In the case of a conventional photosensitive composition using a polyimide-polyamic acid copolymer as a binder resin, the polyamic acid is highly soluble and the polyimide is sparingly soluble in an alkaline aqueous solution. This solubility difference makes it very difficult to control the solubility of the photosensitive composition between exposed and unexposed regions during development, resulting in low resolution of a final pattern.

Thus, there is an urgent need to develop a positive type photosensitive resin composition whose solubility in an alkaline aqueous solution is controlled in exposed and unexposed regions during development to achieve high resolution of a final pattern.

### SUMMARY OF THE INVENTION

The present invention provides a positive type photosensitive resin composition whose solubility is easy to control in exposed and unexposed regions during development to achieve high resolution of a final pattern despite the use of a polyimide-polyamic acid copolymer as a binder resin as in a conventional positive type photosensitive resin composition. The present invention also provides a protective film of a semiconductor device that is formed using the photosensitive resin composition. The protective film is very stable over time.

The present inventors have conducted intensive studies to solve the problem of a conventional polyimide-polyamic acid copolymer that the solubility difference of the polyimide and polyamic acid in exposed and unexposed regions during development results in low resolution of a final pattern. As a result, the inventors have found that when carboxyl groups were introduced into the polyimide moieties of a polyimide-polyamic acid copolymer, the solubility of the polyimide-polyamic acid copolymer in an alkaline aqueous solution was improved, and that when the hydroxyl groups of the polyamic acid moieties of the polyimide-polyamic acid copolymer was structurally modified by hydrogen bonding with a photoactive compound (PAC), the polyimide-polyamic acid copolymer was not dissolved in an exposed region during development. The present invention has been accomplished based on these findings.

Thus, it is an object of the present invention to provide a polyimide-polyamic acid copolymer that has a structure to cause the solubility difference in exposed/unexposed regions during development.

It is another object of the present invention to provide a method for producing the polyimide-polyamic acid copolymer.

It is another object of the present invention to provide a photosensitive resin composition using the polyimide-polyamic acid copolymer as a binder resin.

It is still another object of the present invention to provide a protective film of an organic light emitting diode (OLED) or a semiconductor device that is composed of a polyimide film formed using the polyimide-polyamic acid copolymer and is very stable over time.

According to an aspect of the present invention, there is provided a polyimide-polyamic acid copolymer represented by Formula 1 or 2:

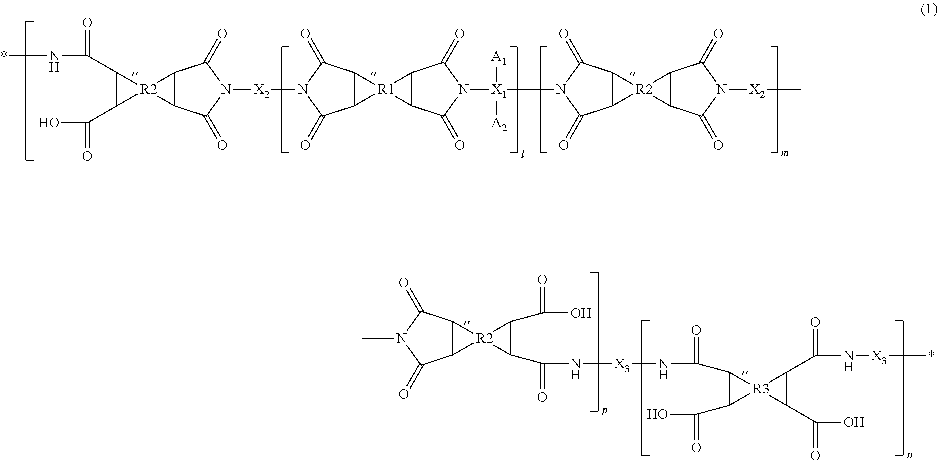

wherein R1, R2 and R3, which may be the same or different, each represents a tetravalent functional group derived from a carboxylic dianhydride, X₁, X₂ and X₃, which may be the same or different, each represents a divalent organic group derived from a diamine, at least one of A₁ and A₂ is a substituent selected from the group consisting of hydroxyl, phenolic hydroxyl and carboxyl groups, 1 and m are integers from 1 to 10, with the proviso that the ratio of 1 to m is from 1:10 to 10:1, and n and p are integers from 1 to 100, with the proviso that the ratio of n to p is from 0.5:1 to 2:1;

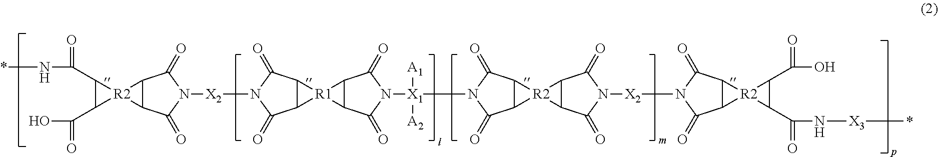

wherein R1 and R2, which may be the same or different, each represents a tetravalent functional group derived from a carboxylic dianhydride, X₁, X₂ and X₃, which may be the same or different, each represents a divalent organic group derived from a diamine, at least one of A₁ and A₂ is a substituent selected from the group consisting of hydroxyl, phenolic hydroxyl and carboxyl groups, 1 and m are integers from 1 to 10, with the proviso that the ratio of 1 to m is from 1:10 to 10:1, and p is an integer from 1 to 100, preferably from 5 to 50.

According to another aspect of the present invention, there is provided a method for producing the polyimide-polyamic acid copolymer of Formula 1, which comprises reacting a first dianhydride with a first diamine to prepare an oligoimide, reacting a second dianhydride with a second diamine to prepare an oligoamic acid, and condensing the oligoimide with the oligoamic acid.

According to another aspect of the present invention, there is provided a method for producing the polyimide-polyamic acid copolymer of Formula 2, which comprises reacting a dianhydride with a first diamine to prepare an oligoimide, and reacting the oligoimide with a second diamine.

According to another aspect of the present invention, there is provided a photosensitive resin composition comprising the polyimide-polyamic acid copolymer.

According to yet another aspect of the present invention, there is provided a protective film of an organic light emitting diode (OLED) or a semiconductor device, which is composed of a polyimide film formed using the polyimide-polyamic acid copolymer.

### DETAILED DESCRIPTION OF THE INVENTION

Exemplary embodiments of the present invention will now be described in more detail.

The present invention provides a polyimide-polyamic acid copolymer represented by Formula 1 or 2:

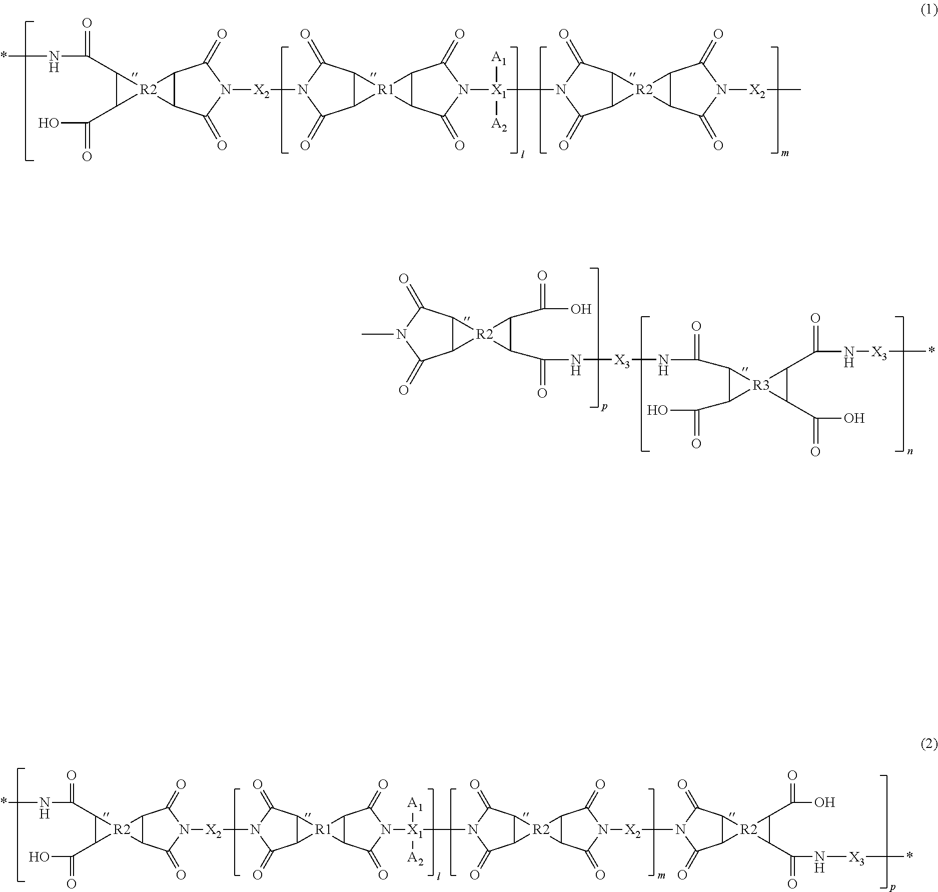

The tetravalent functional groups R1, R2 and R3 in Formula 1 and R1 and R2 in Formula 2 may be the same or different and each is derived from a dianhydride selected from aromatic, alicyclic and aliphatic carboxylic dianhydrides. Specific examples of the dianhydrides include butanetetracarboxylic dianhydride, pentanetetracarboxylic dianhydride, hexanetetracarboxylic dianhydride, cyclopentanetetracarboxylic dianhydride, bicyclohexanetetracarboxylic dianhydride, cyclopropanetetracarboxylic dianhydride, methylcyclohexanetetracarboxylic dianhydride, 3,3′,4,4′-benzophenonetetracarboxylic dianhydride, pyromellitic dianhydride, 3,4,9,10-perylenetetracarboxylic dianhydride, 4,4-sul fonyldiphthalic dianhydride, 3,3′,4,4′-biphenyltetracarboxylic dianhydride, 1,2,5,6-naphthalenetetracarboxylic dianhydride, 2,3,6,7-naphthalenetetracarboxylic dianhydride, 1,4,5,8-naphthalenetetracarboxyl ic dianhydride, 2,3,5,6-pyridinetetracarboxylic dianhydride, m-terphenyl-3,3′,4,4′-tetracarboxylic dianhydride, p-terphenyl-3,3′,4,4′-tetracarboxylic dianhydride, 4,4-oxydiphthalic dianhydride, 1,1,1,3,3,3-hexafluoro-2,2-bis(2,3-dicarboxyphenoxy)phenylpropane dianhydride, 1,1,1,3,3,3-hexafluoro-2,2-bis(3,4-dicarboxyphenoxy)phenylpropane dianhydride, 2,2-bis[4-(2,3-dicarboxyphenoxy)phenyl]propane dianhydride, 2,2-bis[4-(3,4-dicarboxyphenoxy)phenyl]propane dianhydride, 1,1,1,3,3,3-hexafluoro-2,2-bis[4-(2,3-dicarboxyphenoxy)phenyl]propane dianhydride and 1,1,1,3,3,3-hexafluoro-2,2-bis[4-(3,4-dicarboxyphenoxy)phenyl]propane dianhydride.

The divalent organic groups X₂ and X₃ in Formula 1 and X₂ and X₃ in Formula 2 may be the same or different and each of the divalent organic groups is derived from a diamine selected from aliphatic, alicyclic and aromatic diamines. Specific examples of the diamines include m-phenylenediamine, p-phenylenediamine, m-xylylenediamine, p-xylylenediamine, 1,5-diaminonaphthalene, 3,3′-dimethylbenzidine, 4,4-diaminodiphenylmethane, 3,4’-diaminodiphenylmethane, 3,3′-diaminodiphenylmethane, 2,4′-diaminodiphenylmethane, 2,2′-diaminodiphenylmethane, 4,4′-diaminodiphenyl ether, 3,4′-diaminodiphenyl ether, 3,3′-diaminodiphenyl ether, 2,4′-diaminodiphenyl ether, 2,2′-diaminodiphenyl ether, 4,4′-diaminodiphenyl sulfide, 3,4′-diaminodiphenyl sulfide, 3,3′-diaminodiphenyl sulfide, 2,4′-diaminodiphenyl sulfide, 2,2′-diaminodiphenyl sulfide, 4,4′-diaminodiphenylsulfone, 3,4-diaminodiphenylsulfone, 3,3′-diaminodiphenylsulfone, 2,4′-diaminodiphenylsulfone, 2,2′-diaminodiphenylsulfone, 1,1,1,3,3,3-hexalluoro-2,2-bis(4-aminophenyl)propane, 2,2-bis(4-(4-aminophenoxy)phenyl)propane, 4,4-benzophenonediamine, 4,4′-di-(4-aminophenoxy)phenylsulfone, 3,3-dimethyl-4,4-diaminodiphenylmethane, 4,4′-di-(3-aminophenoxy)phenylsulfone, 2,4-diaminotoluene, 2,5-diaminotoluene, 2,6-diaminotoluene, benzidine, o-tolidine, 4,4′-diaminoterphenyl, 2,5-diaminopyridine, 4,4′-bis(p-aminophenoxy)biphenyl and hexahydro-4,7-methanoindanylenedimethylenediamine.

At least one of A₁ and A₂ attached to the divalent organic groups X₁ in Formula 1 and X₁ in Formula 2 is a substituent selected from the group consisting of hydroxyl, phenolic hydroxyl and carboxyl groups. Specific examples of the divalent organic groups X₁ substituted with A₁ and A₂ include 2,2-bis(4′-amino-3′-hydroxyphenyl)-1,1,1,3,3,3-hexafluoropropane, 2,2-bis(4′-amino-3′-hydroxyphenyl)-2,2-dimethylpropane, 3,5-diaminobenzoic acid, 3,3′-dihydroxybenzidine, 2,2-bis(3-aminoporpyl)-2,2-dihydroxypropane, and 2-hydroxycyclohexyl-1,5-diamine.

The present invention also provides a method for producing the polyimide-polyamic acid copolymer of Formula 1.

Specifically, the method of the present invention comprises reacting a first dianhydride with a first diamine (imidization) to prepare an oligoimide consisting of two imide blocks, reacting a second dianhydride with a second diamine to prepare an oligoamic acid, and condensing the oligoimide with the oligoamic acid.

Specifically, the polyimide-polyamic acid copolymer of Formula 1 is produced by the following procedure.

First, a first dianhydride is reacted with a first diamine under suitable reaction conditions, for example, polymerization conditions for polyimide, to prepare an oligoimide corresponding to the repeating unit indicated by m, another diamine is added thereto, followed by polymerization to prepare another oligoimide corresponding to the repeating unit indicated by 1, completing an oligoimide corresponding to the repeating unit indicated by p.

Then, a second dianhydride and a second diamine are sequentially added and react with each other to prepare a polyamic acid corresponding to the repeating unit indicated by n. The oligoimide is condensed with the polyamic acid to afford the polyimide-polyamic acid copolymer of Formula 1.

The condensation between the anhydride-terminated oligoimide and the amine-terminated oligoamic acid proceeds at a temperature of 0° C. to room temperature for 3 to 24 hr.

The reaction for the formation of the imide blocks as the repeating units indicated by l and m. the reaction for the preparation of the oligoimide corresponding to the repeating unit indicated by p. and the reaction for the preparation of the polyamic acid corresponding to the repeating unit indicated by n can be carried out in continuous operation in a single reactor.

Alternatively, the polyimide-polyamic acid copolymer may be produced by preparing a solution of the oligoimide corresponding to the repeating unit indicated by p from the imide blocks as the repeating units indicated by l and m, reacting the second dianhydride with the second diamine to prepare a solution of the oligoamic acid, and subjecting the two solutions to polycondensation.

Various kinds of solvents can be used for the preparation of the oligoimide solution and the oligoamic acid solution. Examples of solvents suitable for use in the method of the present invention include: dimethylformamide, N-methylpyrrolidone, dimethylacetamide and dimethyldisulfoxide, which are used for the preparation of the polyamic acid; tetrahydrofuran; xylene; and dichlorobenzene.

The present invention also provides a method for producing the polyimide-amic acid copolymer of Formula 2. Specifically, the polyimide-amic acid copolymer of Formula 2 can be produced by reacting a dianhydride with a first diamine to prepare an oligoimide and adding a second diamine to the oligoimide. By the addition of the second diamine, amic acid moieties are repeated at the ends of the oligoimide, instead of the oligoamic acid moieties in the compound of Formula 2.

The ratio of molar equivalents of the oligoimide to the oligoamic acid used in the production of the copolymer of Formula 1 is preferably from 0.5:1 to 2:1. The ratio of molar equivalents of the oligoimide to the second diamine used in the production of the copolymer of Formula 2 is preferably from 0.5:1 to 2:1.

The polyimide-polyamic acid copolymer of the present invention is produced by condensing a solution of the dianhydride-terminated oligoimide with a solution of the diamine-terminated oligoamic acid with stirring. The polyimide-polyamic acid copolymer is terminated with carboxylic acid or amine groups.

If needed, crosslinkable end groups may be introduced into the polyimide-polyamic acid copolymer to synthesize a compound of Formula 3:

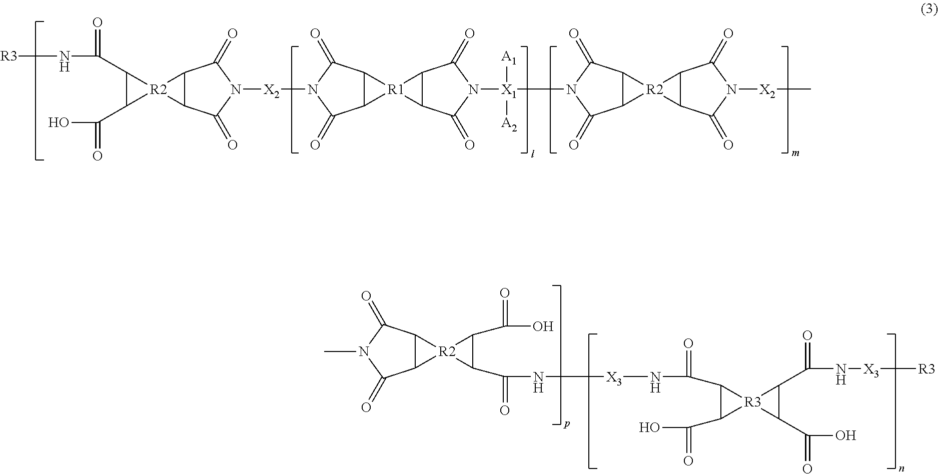

wherein l and m are integers from 1 to 10, with the proviso that the ratio of 1 to m is from 1:10 to 10:1, n and p are integers from 1 to 100, with the proviso that the ratio of n to p is from 0.5:1 to 2:1, R1, R2, X₁, X₂, X₃, A₁ and A₂ are as defined in Formula 1, and each R3 is a group derived from an anhydride.

Each of the crosslinkable end groups R3 is derived from an anhydride selected from the group consisting of maleic anhydride, dimethylmaleic anhydride, norbornene dicarboxylic anhydride and ethynylphenyl anhydride.

The polyimide-polyamic acid copolymer of Formula 1 to 3 preferably has a weight average molecular weight of 20,000 to 200,000 and a glass transition temperature (T_{g}) of 250 to 400° C.

The present invention also provides a photosensitive resin composition comprising the polyimide-polyamic acid copolymer of Formula 1 to 3, a photoactive compound (PAC), and a solvent.

The polyimide-polyamic acid copolymer is present in an amount of 10 to 45% by weight, based on the total weight of the photosensitive resin composition. The photoactive compound is used in an amount of 10 to 40 parts by weight and preferably 12 to 27 parts by weight, based on 100 parts by weight of the polyimide-polyamic acid copolymer.

The photoactive compound may be selected from diazonaphthoquinone compounds represented by Formulas 4 to 7:

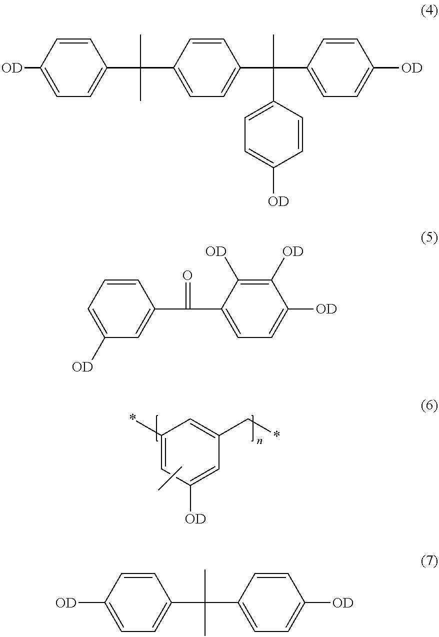

wherein D is selected from

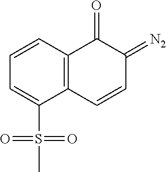

and hydrogen.

The solvent is selected from y-butyrolactone, dimethylacetamide, N-methylpyrrolidone and dimethylsulfoxide. The solvent content is determined at a level that is comparable to that in known photosensitive compositions.

The photosensitive composition may further comprise a small amount of ethyl lactate or 4-butoxyethanol for better coatability. It is to be understood that at least one known additive may be added in such an amount as not to deteriorate the physical properties of the photosensitive composition.

The photosensitive resin composition of the present invention can attain higher resolution of a final pattern than conventional resin compositions comprising polyamic acids.

A conventional resin composition comprising a polyamic acid is excessively developed with an alkaline aqueous solution due to the high solubility of the polyamic acid. In contrast, the solubility of the polymide of the polyimide-polyamic acid copolymer of Formula 1 to 3 in an alkaline aqueous solution increases and the hydroxyl (OH) groups of the polyamic acid are hydrogen bonded with the PAC. Therefore, the polyimide-polyamic acid copolymer is not substantially dissolved in the alkaline aqueous solution in an unexposed region during development. The PAC is decomposed and is thus readily soluble in the alkaline aqueous solution in an exposed region during development, which makes the polyimide-polyamic acid copolymer soluble in the alkaline aqueous solution. As a result, high resolution of a final pattern formed using the photosensitive resin composition can be achieved.

The photosensitive resin composition of the present invention is coated on a silicon wafer by a suitable coating technique, such as spin coating, roll coating or slit coating. The coated wafer is dried at 120° C. for 2 min to evaporate the solvent. The film is exposed through a patterned photomask. The exposure may be performed under monochromatic ultraviolet (UV) light (e.g., i-, g- or h-line) or polychromatic UV light. The exposure dose may vary depending on the thickness of the film. Typically. UV light at an exposure dose of 50 to 1,000 mJ/cm² is irradiated on the film

Then, the exposed film is developed with an alkaline solution, such as an aqueous solution of sodium carbonate, sodium bicarbonate, sodium hydroxide or tetramethylammonium hydroxide. An aqueous 0.38-2.39 wt % tetramethylammonium hydroxide solution is generally used as the alkaline solution. The development may be performed for about 30 to about 120 sec. Thereafter, the developed film is dipped in distilled water for 10 to 30 sec. This procedure gives a positive type pattern corresponding to the photomask pattern at a desired location on the wafer.

The patterned film is baked to provide a polyimide film. It is preferred to perform the baking on a hot plate or in an oven at a temperature between 230 and 350° C. under a nitrogen atmosphere for 0.5 to 1 hr. The baked film is preferably dried under vacuum. As a result, the polyimide-polyamic acid copolymer is converted into a polyimide.

The present invention also provides a protective film of an OLED or a semiconductor device that is composed of a polyimide film formed using the photosensitive composition. The polyimide film protects pixels between electroluminescent (EL) layers of an OLED. Further, the polyimide film may be used as a buffer film between epoxy and silicon nitrite layers of a semiconductor device. The protective film of the present invention is very stable over time.

Hereinafter, the present invention will be explained in more detail with reference to the following examples. However, these examples are not intended to limit the present invention and technology extendibility in the art to which the invention pertains should be taken into consideration.

### EXAMPLES

### Synthesis Example 1

### Synthesis of PI-b-PAA-1

10 mmol of diphenyl ether dianhydride (ODPA) and 5 mmol of diaminophenyl ether (ODA) were dissolved in 50 mL of NMP and 10 mL of toluene. The solution was allowed to react at 180° C. for 3 hr while removing water by azeotropic distillation. After the reaction solution was cooled to room temperature, 5 mL of toluene and 3 mmol of bis(4-hydroxy-3-aminophenyl)hexafluoromethane were added thereto. The resulting mixture was reacted at 180° C. for 3 hr. The azeotropic distillation column was removed. Heating was continued for 1 hr to remove the toluene. The reaction solution was cooled to room temperature, and then 3 mmol of pyromellitic dianhydride and 5 mmol of diaminophenyl ether were sequentially added thereto. The mixture was reacted with stirring at room temperature for 18 hr to yield a polyimide-polyamic acid copolymer PI-b-PAA-1.

GPC and DSC analyses showed that the copolymer had a weight average molecular weight of 34,000 and a glass transition temperature (T_{g}) of 255° C., respectively.

### Synthesis Example 2

### Synthesis of PI-b-PAA-2

10 mmol of diphenyl ether dianhydride (ODPA) and 5 mmol of diaminophenyl ether (ODA) were dissolved in 50 mL of NMP and 10 mL of toluene. The solution was allowed to react at 180° C. for 3 hr while removing water by azeotropic distillation. After the reaction solution was cooled to room temperature, 5 mL of toluene and 3 mmol of bis(4-hydroxy-3-aminophenyl)hexafluoromethane were added thereto. The resulting mixture was reacted at 180° C. for 3 hr. The azeotropic distillation column was removed. Heating was continued for 1 hr to remove the toluene. The thus prepared oligoimide solution was stored at room temperature. 2.53 mmol of pyromellitic dianhydride and 5 mmol of diaminophenyl ether were sequentially added to another flask, and the mixture was reacted with stirring at room temperature for 15 hr. The reaction solution was mixed with the oligoimide solution, followed by stirring for 5 hr. After 1 mmol of maleic anhydride was added, stirring was continued for additional 10 hr to yield a polyimide-polyamic acid copolymer Pl-b-PAA-2 having terminal functional groups derived from the maleic anhydride.

GPC and DSC analyses showed that the copolymer had a weight average molecular weight of 27,500 and a glass transition temperature (T_{g}) of 295° C. respectively.

### Synthesis Example 3

### Synthesis of PI-b-DA-1

10 mmol of diphenyl ether dianhydride (ODPA) and 3 mmol of diaminophenyl ether (ODA) were dissolved in 50 mL of NMP and 10 mL of toluene. The solution was allowed to react at 180° C. for 3 hr while removing water by azeotropic distillation. After the reaction solution was cooled to room temperature. 5 ml. of toluene and 3 mmol of bis(4-hydroxy-3-aminophenyl)hexafluoromethane were added thereto. The resulting mixture was reacted at 180° C. for 3 hr. The azeotropic distillation column was removed. Heating was continued for 1 hr to remove the toluene. The thus prepared oligoimide solution was cooled to room temperature, and then 4.5 mmol of diaminophenyl ether was added thereto. The mixture was stirred at room temperature for 5 hr. After 1 mmol of norbornene anhydride was added, stirring was continued for 15 hr to yield a polyimide-amic acid copolymer PI-b-DA-2 having terminal functional groups derived from the norbornene anhydride.

GPC and DSC analyses showed that the copolymer had a weight average molecular weight of 31,000 and a glass transition temperature (T_{g}) of 235° C., respectively.

### Comparative Synthesis Example 1

### Synthesis of sPI-1

10.3 mmol of diphenyl ether dianhydride (ODPA) and 2 mmol of diaminophenyl ether (ODA) were dissolved in 40 mL of NMP and 10 mL of toluene. The solution was allowed to react at 180° C. for 3 hr while removing water by azeotropic distillation. After the reaction solution was cooled to room temperature, 5 mL of toluene and 8 mmol of bis(4-hydroxy-3-aminophenyl)hexafluoromethane were added thereto. The resulting mixture was reacted at 180° C. for 3 hr. The azeotropic distillation column was removed. Heating was continued for 1 hr to remove the toluene. The solution was cooled to room temperature to yield a polyimide sPI-1.

GPC and DSC analyses showed that the polymer had a weight average molecular weight of 131,000 and a glass transition temperature (T_{g}) of 315° C., respectively.

### Comparative Synthesis Example 2

### Synthesis of PAA-1

10 mmol of diphenyl ether dianhydride (ODPA) and 10.5 mmol of diaminophenyl ether (ODA) were dissolved in 80 mL of NMP. Stirring of the solution for 18 hr afforded a polyamic acid PAA-1.

GPC and DSC analyses showed that the polymer had a weight average molecular weight of 111,000 and a glass transition temperature (T_{g}) of 305° C., respectively.

### Example 1

### Preparation and Characteristics of PSPI-1

To 20 mL of a solution of PI-b-PAA-1 (25 wt %) was added 1.5 g of TPPA320 of Formula 4 wherein two of the three substituents D are diazonaphthoquinone sulfate groups and the other substituent is hydrogen. The addition of 2 mL of 2-butoxyethanol gave a solution PSPI-1. The solution was spin-coated on a silicon wafer to form an 11 μm thick film. The film was exposed to UV (365 nm (i-line)) with an energy of 600 mi/cm² through a patterned photomask, developed with an aqueous 2.38% tetramethylammonium hydroxide solution for 120 sec, washed with distilled water for 60 sec, and dried to form an 8 μm thick pattern. The pattern had a minimum hole size of 1 μm. The patterned film was cured at 350° C. for 30 min to obtain a patterned polyimide film. The rectilinearity of the line pattern was clean and good. The pattern had a minimum hole size of 3 μm and a thickness of 8 μm.

### Example 2

### Preparation and Characteristics of PSPI-2

To 30 mL of a solution of PI-b-PAA-2 (23 wt %) was added 2.0 g of TPPA320 of Formula 4 wherein two of the three substituents D are diazonaphthoquinone sulfate groups and the other substituent is hydrogen. The addition of 2.5 mL of 2-butoxyethanol gave a solution PSPI-2. The solution was spin-coated on a silicon wafer to form an 11 μm thick film. The film was exposed to UV (365 nm (i-line)) with an energy of 450 mJ/cm² through a patterned photomask, developed with an aqueous 2.38% tetramethylammonium hydroxide solution for 120 sec, washed with distilled water for 60 sec, and dried to form a desired mask pattern. The patterned film was cured at 350° C. for 30 min to obtain a patterned polyimide film. The pattern had a minimum hole size of 4 μm and a thickness of 7 μm. The rectilinearity of the line pattern was clean and good.

### Example 3

### Preparation and Characteristics of PSPI-3

To 20 mL of a solution of PI-b-DA-1 (20 wt %) was added 1.5 g of M425 of Formula 5 wherein the number of diazonaphthoquinone sulfate groups in the four substituents D is an average of 2.5 and the other substituent is hydrogen. The addition of 2 mL of 2-butoxyethanol gave a solution PSPI-3. The solution was spin-coated on a silicon wafer to form an 11 μm thick film. The film was exposed to UV (365 nm (i-line)) with an energy of 300 mJ/cm² through a patterned photomask, developed with an aqueous 2.38% tetramethylammonium hydroxide solution for 120 sec, washed with distilled water for 60 sec, and dried to form a desired mask pattern. The patterned film was cured at 350° C. for 30 min to obtain a patterned polyimide film. The pattern had a minimum hole size of 3 μm and a thickness of 8 μm. The rectilinearity of the line pattern was clean and good.

### Comparative Example 1

### Preparation and Characteristics of CPI-1 (Photosensitive sPI-1)

To 20 mL of a solution of sPI-1 (30 wt %) was added 2.3 g of M425 of Formula 5 wherein the number of diazonaphthoquinone sulfate groups in the four substituents D is an average of 2.5 and the other substituent is hydrogen. The addition of 2.7 mL of 2-butoxyethanol gave a solution CPI-1. The solution was spin-coated on a silicon wafer to form a 9 μm thick film. The film was exposed to UV (365 nm (i-line)) with an energy of 1,200 mJ/cm² through a patterned photomask, developed with an aqueous 2.38% tetramethylammonium hydroxide solution for 120 sec, washed with distilled water for 60 sec, and dried to form a desired mask pattern. The patterned film was cured at 350° C. for 30 min to obtain a patterned polyimide film. The pattern had a minimum hole size of 30 μm and a thickness of 6 μm. The rectilinearity of the line pattern was good.

### Comparative Example 2

### Preparation and Characterization Experiments of CPI-2 (Photosensitive PAA-1)

To 20 mL of a solution of PAA-1 (20 wt %) was added 2.0 g of TPPA320 of Formula 4 wherein two of the three substituents D are diazonaphthoquinone sulfate groups and the other substituent is hydrogen. The addition of 2.5 mL of 2-butoxyethanol gave a solution CPI-2. The solution was spin-coated on a silicon wafer to form a 12 μm thick film. The film was exposed to UV (365 nm (i-line)) with an energy of 100 mJ/cm² through a patterned photomask, developed with an aqueous 2.38% tetramethylammonium hydroxide solution for 120 sec, washed with distilled water for 60 sec, and dried to form a desired mask pattern. The patterned film was cured at 350° C. for 30 min to obtain a patterned polyimide film. The pattern had a minimum hole size of 20 μm and a thickness of 8 μm. The rectilinearity of the line pattern was good.

### Comparative Example 3

### Preparation and Characterization Experiments of CPI-3 (Photosensitive PI+PAA-1)

10 mL of a solution of sPI-I (30 wt %) was mixed with 5 mL of a solution of PAA-1 (20 wt %). To the mixture was added 2.0 g of TPPA320 of Formula 4 wherein two of the three substituents D are diazonaphthoquinone sulfate groups and the other substituent is hydrogen. The addition of 5 mL of N-methylpyrrolidinone and 2.5 mL of 2-butoxyethanol gave a solution CPI-3. The solution was spin-coated on a silicon wafer to form a 12 μm thick film. The film was exposed to UV (365 nm (i-line)) with an energy of 700 mJ/cm² through a patterned photomask, developed with an aqueous 2.38% tetramethylammonium hydroxide solution for 120 sec, washed with distilled water for 60 sec. and dried to form a pattern. The patterned film was cured at 350° C. for 30 min to obtain a patterned polyimide film. The pattern had a minimum hole size of 10 μm and a thickness of 8 μm. The rectilinearity of the line pattern was distorted and was very dirty.

TABLE 1

| | | Resolution | |
|---|---|---|---|
| | | (minimum | Aspect |
| Example No. | Pattern shape | hole size, μm) | Ratio* |
| Example 1 | Good | 1 | 8 |
| Example 2 | Good | 4 | 1.75 |
| Example 3 | Good | 3 | 2.67 |
| Comparative Example 1 | Good | 30 | 0.2 |
| Comparative Example 2 | Good | 20 | 0.4 |
| Comparative Example 3 | Poor | 10 | 1.25 |

*Aspect ratio = Pattern thickness/pattern size

A higher aspect ratio of the pattern means better resolution. As can be known from the results in Table 1, the patterns formed using the photosensitive resin compositions of Examples 1-3 had higher resolutions at a desired level because the acid values of the polyimide-polyamic acid copolymers were controlled.

### Experimental Example 1

### Developability (Alkaline Developing Rate (ADR))

The developability of the films formed in Examples 1-3 and Comparative Examples 1-3 was tested using an aqueous 2.38% tetramethylammonium hydroxide solution as an alkaline developing solution. First, each of the solutions prepared in Examples 1-3 and Comparative Examples 1-3 was coated on a silicon wafer, and prebaked at 120° C. for 3 min to a 10 μm thick film. The coated silicon film was dipped in an aqueous 2.38% tetramethylammonium hydroxide solution. The time required for 100% dissolution of the film was measured. The time (sec) was divided by the thickness (A) of the film to determine the developing rate of the film. The results are shown in Table 2.

TABLE 2

| Sample | Dissolution rate (Å′sec) |
|---|---|
| Example 1 | 1,223 |
| Example 2 | 1,450 |
| Example 3 | 1,552 |
| Comparative Example 1 | 2,500 |
| Comparative Example 2 | 10,200 |
| Comparative Example 3 | 1,800 |

A dissolution rate (etching rate) needed for a 10 μm thick film to be developed in the unexposed region for a general developing time (100-120 sec) is preferably between 900 and 1,300 Å/sec. The results in Table 2 reveal that the films formed in Examples 1-3 had dissolution rates at an appropriate level.

As is apparent from the above description, the solubility of the polyimide-polyamic acid copolymer according to the present invention in exposed and unexposed regions during development is controlled to achieve high resolution of a final pattern. In addition, a protective film formed using the polyimide-polyamic acid copolymer of the present invention is very stable over time. A photosensitive polyimide film formed using the photosensitive composition of the present invention can be used as a protective film of an OLED or a semiconductor device. The photosensitive polyimide film protects pixels between electroluminescent (EL) layers of the OLED. Further, the polyimide film can be used as a buffer film between epoxy and silicon nitrite layers of the semiconductor device.

1. A photosensitive resin com osition com risin 10 to 45% by weight of a polyimide-polyamic acid copolymer represented by Formula 1 or 2: 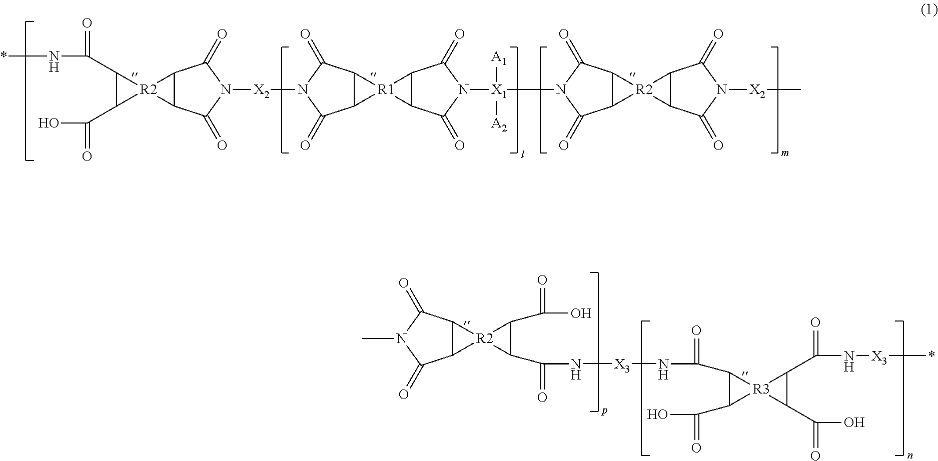
wherein R1, R2 and R3 are the same or different and each represents a tetravalent functional group derived from a carboxylic dianhydride, X₁, X₂ and X₃ are the same or different and each represents a divalent organic group derived from a diamine, at least one of A₁ and A₂ is a substituent selected from the group consisting of hydroxyl, phenolic hydroxyl and carboxyl groups, 1 and m are integers from 1 to 10, with the proviso that the ratio of 1 to m is from 1:10 to 10:1, and n and p are integers from 1 to 100, with the proviso that the ratio of n to p is from 0.5:1 to 2:1; 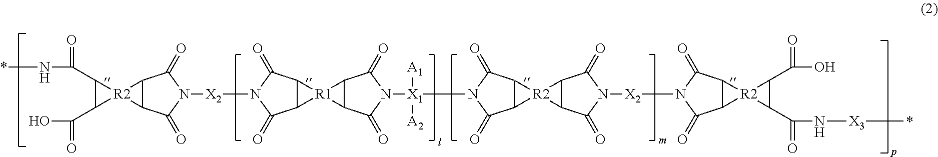
wherein R1 and R2 are the same or different and each represents a tetravalent functional group derived from a carboxylic dianhydride, X₁, X₂ and X₃ are the same or different and each represents a divalent organic group derived from a diamine, at least one of A₁ and A₂ is a substituent selected from the group consisting of hydroxyl, phenolic hydroxyl and carboxyl groups, l and m are integers from 1 to 10, with the proviso that the ratio of l to m is from 1:10 to 10:1, and p is an integer from 1 to 100.

2. The photosensitive resin composition of claim 1, wherein the copolymer has a weight average molecular weight of 20,000 to 200,000 and a glass transition temperature of 250 to 400° C.

3-9. (canceled)

10. The photosensitive resin composition of claim 1, wherein the composition comprises a photoactive compound selected from compounds represented by Formulas 4 to 7: 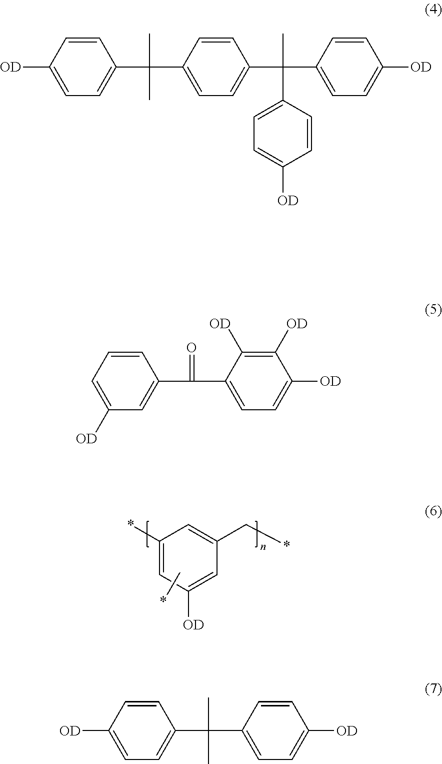
wherein D is 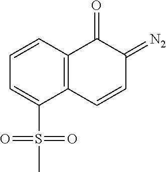
or hydrogen.

11. (canceled)

12. An insulating film of an organic light emitting diode (OLED) or a semiconductor device, the insulating film being composed of a polyimide film formed using the photosensitive resin composition of claim 1.

13. (canceled)

14. A method for producing the polyimide-polyamic acid copolymer represented by Formula (1), the method comprising:
reacting a first dianhydride with a first diamine to prepare an oligoimide;
reacting a second dianhydride with a second diamine to prepare an oligoamic acid; and
condensing the oligoimide with the oligoamic acid, 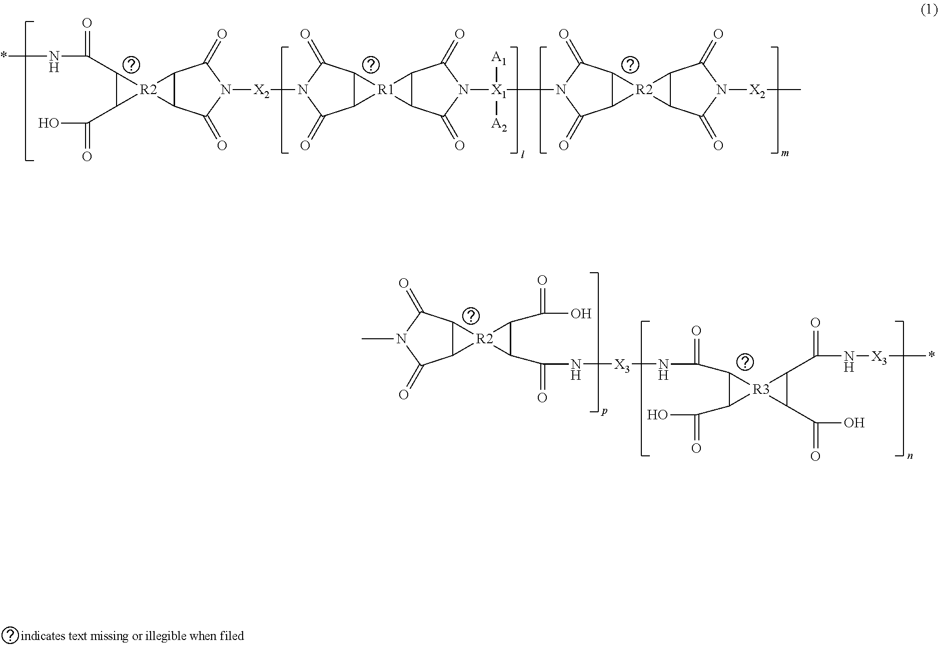
wherein R1, R2 and R3 are the same or different and each represents a tetravalent functional group derived from a carboxylic dianhydride, X₁, X₂ and X₃ are the same or different and each represents a divalent organic group derived from a diamine, at least one of A₁ and A₂ is a substituent selected from the group consisting of hydroxyl, phenolic hydroxyl and carboxyl groups, l and m are integers from 1 to 10, with the proviso that the ratio of l to m is from 1:10 to 10:1, and n and p are integers from 1 to 100, with the proviso that the ratio of n to p is from 0.5:1 to 2:1.

15. The method of claim 14, wherein the ratio of molar equivalents of the oligoimide to the oligoamic acid is from 0.5:1 to 2:1.

16. The method of 14, further comprising, after the condensation, reacting the polyimide-polyamic acid copolymer with an anhydride selected from the group consisting of maleic anhydride, dimethylmaleic anhydride, norbornene dicarboxylic anhydride and ethynylphenyl anhydride.

17. The method of claim 16, wherein the reaction product is a compound represented by Formula (3): 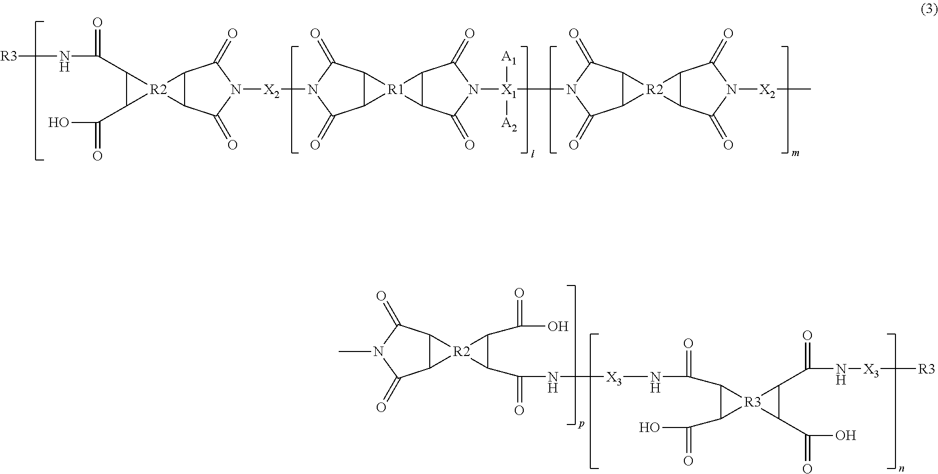
wherein l and m are integers from 1 to 10, with the proviso that the ratio of l to m is from 1:10 to 10:1, n and p are integers from 1 to 100, with the proviso that the ratio of n to p is from 0.5:1 to 2:1, R1, R2, X₁, X₂, X₃, A₁ and A₂ are as defined in Formula 1, and each R3 is a group derived from an anhydride.

18. A method for producing the polyimide-polyamic acid copolymer represented by Formula 2, the method comprising:
reacting a dianhydride with a first diamine to prepare an oligoimide; and
reacting the oligoimide with a second diamine, 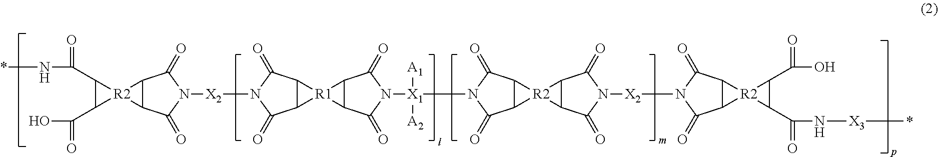
wherein R1 and R2 are the same or different and each represents a tetravalent functional group derived from a carboxylic dianhydride, X₁, X₂ and X ₃ are the same or different and each represents a divalent organic group derived from a diamine, at least one of A₁ and A₂ is a substituent selected from the group consisting of hydroxyl, phenolic hydroxyl and carboxyl groups, l and m are integers from 1 to 10, with the proviso that the ratio of l to m is from 1:10 to 10:1, and p is an integer from 1 to 100.

19. A photosensitive resin composition comprising 10 to 45% by weight of the polyimide-polyamic acid copolymer produced by the method of claim 18, based on the total weight of the composition.

20. The photosensitive resin composition of claim 19, wherein the composition comprises a photoactive compound selected from compounds represented by Formulas (4) to (7): 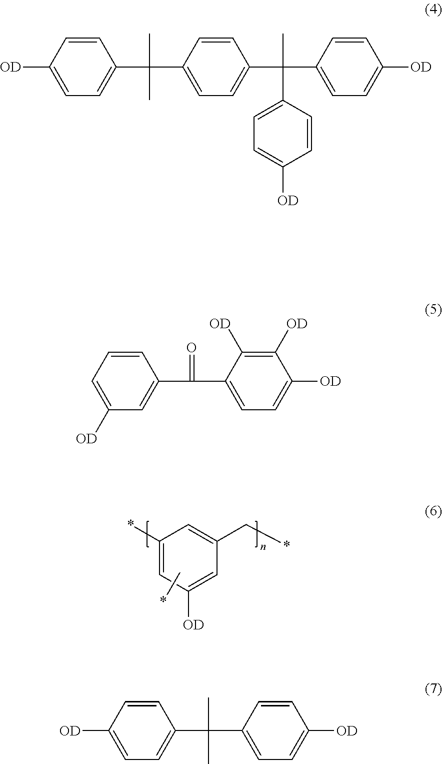
wherein D is 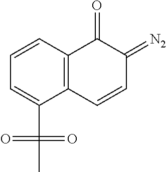
or hydrogen.

21. An insulating film of an organic light emitting diode (OLED) or a semiconductor device, the insulating film being composed of a polyimide film formed using the photosensitive resin composition of claim 19.
